(19) United States
(12) Patent Application Publication
(10) Pub. No.: US 2017/0250331 A1
(43) Pub. Date: Aug. 31, 2017

(54) LIGHT EMITTING DEVICE PACKAGE AND LIGHT EMITTING MODULE COMPRISING SAME

(71) Applicant: LG INNOTEK CO., LTD., Seoul (KR)

(72) Inventor: Ji Na KWON, Seoul (KR)

(21) Appl. No.: 15/519,723

(22) PCT Filed: Oct. 6, 2015
(86) PCT No.: PCT/KR2015/010531

§ 371 Date: Apr. 17, 2017

(30) Foreign Application Priority Data
Oct. 17, 2014 (KR) 10-2014-0140676

(51) Int. Cl. H01L 33/62; H01L 33/56; H01L 23/00; H01L 33/48; H01L 33/60

(52) U.S. Cl. CPC H01L 33/62; H01L 33/486; H01L 33/60; H01L 24/48; H01L 24/73; H01L 33/56; H01L 2224/48091; H01L 2224/48257; H01L 2224/73265; H01L 2924/12041

(57) ABSTRACT

A light emitting device package according to an embodiment comprises: a package body; a lead frame arranged on the package body; and a light emitting device arranged on the lead frame; an adhesive member arranged between the light emitting device and the lead frame; and a resin layer surrounding the light emitting device, wherein the package body comprises a resin and a volatile corrosion inhibitor which is mixed with the resin.

### CROSS-REFERENCE TO RELATED PATENT APPLICATIONS

This application is a U.S. National Stage application under 35 U.S.C. §371 of PCT Application No. PCT/KR2015/010531, filed Oct. 6, 2015, which claims priority to Korean Patent Application No. 10-2014-0140676, filed Oct. 17, 2014, whose entire disclosures are hereby incorporated by reference.

### TECHNICAL FIELD

Embodiments relate to a light-emitting device package and a light-emitting module having the same.

### BACKGROUND ART

Light-Emitting devices, such as Light-emitting Diodes (LEDs) or laser diodes, which use group III-V or group II-VI compound semiconductors, are capable of emitting visible and Ultra Violet (UV) light of various colors, such as red, green, and blue, owing to development of device materials and thin film growth techniques. Moreover, these light-emitting devices are capable of emitting white light with high luminous efficacy through use of fluorescent materials or color combination, and have advantages of low power consumption, semi-permanent lifespan, fast response time, safety and environmental friendliness, compared to conventional light sources such as, for example, fluorescent lamps and incandescent lamps.

Light-emitting device packages are widely used in lighting apparatuses or display apparatuses. Such a light-emitting device package may generally include a body, lead frames located in the body, and a light-emitting device (e.g. LED) located on any one of the lead frames. Here, a metal material constituting the lead frame may easily undergo surface oxidation and discoloration due to a chemical reaction, which may deteriorate the luminous efficacy of the light-emitting device package.

### DISCLOSURE

### Technical Problem

Embodiments provide a light-emitting device package, which may prevent discoloration of a lead frame and may prevent deterioration in luminous efficacy due to the discoloration of the lead frame.

### Technical Solution

In accordance with one embodiment, a light-emitting device package includes a package body, a lead frame disposed on the package body, a light-emitting device disposed on the lead frame, an adhesive member disposed between the light-emitting device and the lead frame, and a resin layer surrounding the light-emitting device, wherein the package body includes a resin and a volatile corrosion inhibitor, and the volatile corrosion inhibitor is mixed with the resin.

The volatile corrosion inhibitor may include at least one selected from among Benzo triazole (BTA), Tolyltriazole (TTA), Dicyclohexyl ammonium nitrite (DICHAN), Dicyclohexyl ammonium salicylate (DICHA-SA), Monoethanolamine benzoate (MEA-BA), Dicyclohexyl ammonium benzoate (DICHA-BA), Diisopropyl ammonium benzoate (DIPA-BA), Diisopropyl ammonium nitrite (DIPAN), Cyclohexylamine carbonate (CHC), Nitro naphthalene ammonium nitrite (NITAN), Cyclohexylamine benzoate (CHA-BA), Dicyclohexyl ammonium cyclohexylamine carboxylate (DICHA-CHC), Cyclohexylamine cyclohexane carboxylate (CHA-CHC), Dicyclohexyl ammonium acrylate (DICHA-AA), and Cyclohexylamine acrylate (CHA-AA).

The volatile corrosion inhibitor may have a weight within a range from 0.01% to 5% relative to an entire weight of the package body. Alternatively, the volatile corrosion inhibitor may have a weight within a range from 0.5% to 3% relative to the entire weight of the package body. Alternatively, the volatile corrosion inhibitor may have a weight within a range from 1% to 2% relative to an entire weight of the package body.

The light-emitting device package may further include a protective layer formed on a surface of the lead frame, and the protective layer may be a compound resulting from a chemical reaction between the lead frame and the volatile corrosion inhibitor. The protective layer may be formed on at least one of an upper surface, a lateral surface, and a lower surface of the lead frame.

The resin layer may include a volatile corrosion inhibitor.

In accordance with another embodiment, a light-emitting device package includes a package body having a cavity including a lateral surface and a bottom, a lead frame disposed on the package body, a light-emitting device disposed on the lead frame inside the cavity, an adhesive member disposed between the light-emitting device and the lead frame, a first protective member disposed on a surface of the package body, and a resin layer that is filled in the cavity so as to surround the light-emitting device, wherein the first protective member includes a volatile corrosion inhibitor.

The first protective member may be disposed on the lateral surface of the cavity.

Alternatively, the first protective member may be disposed on the lateral surface and the bottom of the cavity.

Alternatively, the first protective member may be disposed on at least one of a lateral surface, a lower surface, and an upper surface of the package body.

The light-emitting device package may further include a protective layer formed on at least one of an upper surface, a lateral surface, and a lower surface of the lead frame, and the protective layer may be a compound resulting from a chemical reaction between the lead frame and the volatile corrosion inhibitor.

The lead frame is formed of at least one selected from among titanium (Ti), copper (Cu), nickel (Ni), gold (Au), chrome (Cr), tantalum (Ta), platinum (Pt), tin (Sn), silver (Ag), and phosphorous (P), or an alloy thereof.

The light-emitting device package may further include a wire configured to electrically interconnect the light-emitting device and the lead frame, and a second protective member configured to surround the wire, the second protective member including a volatile corrosion inhibitor.

The adhesive member may be a solder or solder paste.

In accordance with a further embodiment, a light-emitting module includes a board, a plurality of light-emitting device packages disposed on an upper surface of the board, a first adhesive member disposed between the light-emitting device packages and the board, and a protective member disposed on a surface of the board, the protective member including a volatile corrosion inhibitor, wherein each of the light-emitting device packages may be the above-described embodiment.

### Advantageous Effect

Embodiments may provide discoloration of a lead frame and may prevent deterioration in luminous efficacy due to the discoloration of the lead frame.

### DESCRIPTION OF DRAWINGS

FIG. 1 is a plan view of a light-emitting device package according to an embodiment.

FIG. 2 is a cross-sectional view taken in the direction AB of the light-emitting device package illustrated in FIG. 1.

FIG. 3 is a view illustrating the result of analysis of gas volatized from solder flux.

FIG. 4 is a table illustrating the prevention of metal corrosion by a volatile corrosion inhibitor included in a package body.

FIGS. 5a to 5g are cross-sectional views illustrating light-emitting device packages according to other embodiments.

FIGS. 6a and 6b are views illustrating light-emitting modules according to embodiments.

FIG. 7a is a view illustrating the result of discoloration experimentation on an adhesive member of a light-emitting module that does not include an anti-corrosion member illustrated in FIG. 6a.

FIG. 7b is a view illustrating the result of discoloration experimentation of the adhesive member of the light-emitting module illustrated in FIG. 6a.

FIG. 8 is a view illustrating the result of experimentation showing variation in luminous flux over time in the light-emitting module that does not include an anti-corrosion member illustrated in FIG. 6a.

FIG. 9 is a view illustrating the result of experimentation showing variation in luminous flux over time in the light-emitting module illustrated in FIG. 6a.

FIG. 10 is a view illustrating a lighting apparatus including a light-emitting device package according to an embodiment.

FIG. 11 is a view illustrating a display apparatus including a light-emitting device package according to an embodiment.

FIG. 12 is a view illustrating a headlamp including a light-emitting device package according to an embodiment.

### BEST MODE

Hereinafter, embodiments will be clearly revealed with reference to the accompanying drawings and the description of the embodiments. In the description of the embodiments, it will be understood that, when each layer (film), area, pattern, or structure is referred to as being formed “on” or “under” a substrate, each layer (film), area, pad or pattern, it can be directly “on” or “under” the other element or be indirectly formed with intervening one or more elements therebetween. It will also be understood that “on” or “under” the element may be described relative to the drawings.

In the drawings, the thickness or size of each layer may be exaggerated, omitted or schematically illustrated for clarity and convenience. In addition, the size of each constituent element does not wholly reflect an actual size thereof. In addition, the same reference numerals will designate the same elements throughout the description of the drawings.

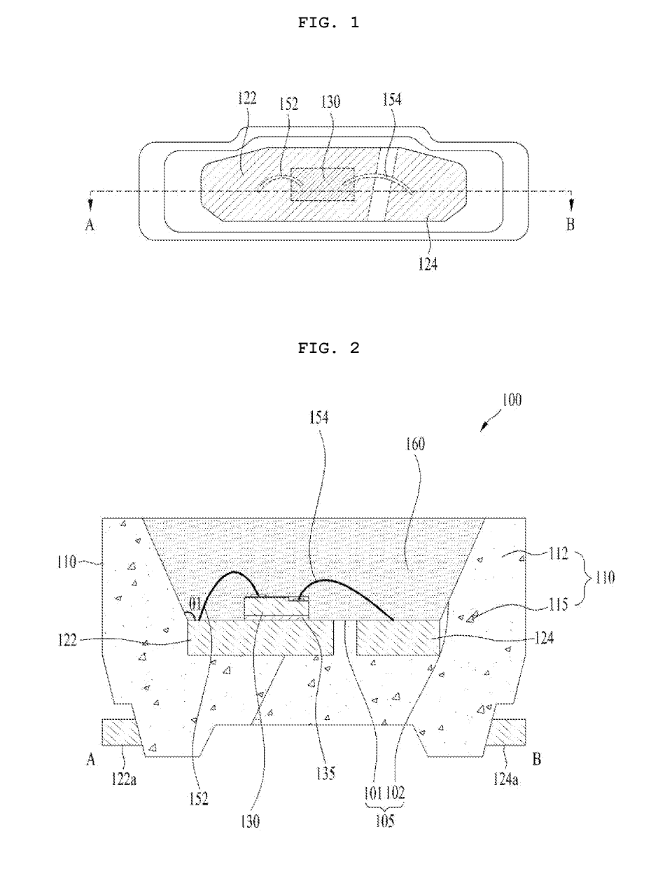

FIG. 1 is a plan view of a light-emitting device package 100 according to an embodiment, and FIG. 2 is a cross-sectional view taken in the direction AB of the light-emitting device package 100 illustrated in FIG. 1.

Referring to FIGS. 1 and 2, the light-emitting device package 100 includes a package body 110, a first lead frame 122, a second lead frame 124, a light-emitting device 130, an adhesive member 135, wires 152 and 154, and a resin layer 160.

The package body 110 may include a resin 112 and a volatile corrosion inhibitor 115. The volatile corrosion inhibitor may be added to the resin and mixed with the resin.

The package body 110 may be a thermo-setting resin having excellent heat resistance, for example, a polyphthalamide (PPA), epoxy mold compound (EMC) resin, or PCT resin that has high reflectance, without being limited thereto.

The volatile corrosion inhibitor included in the package body 110 may include at least one selected from among Benzo triazole (BTA), Tolyltriazole (TTA), Dicyclohexyl ammonium nitrite (DICHAN), Dicyclohexyl ammonium salicylate (DICHA-SA), Monoethanolamine benzoate (MEA-BA), Dicyclohexyl ammonium benzoate (DICHA-BA), Diisopropyl ammonium benzoate (DIPA-BA), Diisopropyl ammonium nitrite (DIPAN), Cyclohexylamine carbonate (CHC), Nitro naphthalene ammonium nitrite (NITAN), Cyclohexylamine benzoate (CHA-BA), Dicyclohexyl ammonium cyclohexylamine carboxylate (DICHA-CHC), Cyclohexylamine cyclohexane carboxylate (CHA-CHC), Dicyclohexyl ammonium acrylate (DICHA-AA), and Cyclohexylamine acrylate (CHA-AA).

For example, the content of the volatile corrosion inhibitor 115 added to the package body 110 may range from 0.01% to 5%. For example, the weight of the volatile corrosion inhibitor 115 relative to the entire weight of the package body 110 may range from 0.01% to 5%. When the content of the volatile corrosion inhibitor 115 added to the package body 110 is below 0.01%, the amount of corrosion inhibitor that is volatized is slight, and discoloration of the first and second lead frames 122 and 124 may not be prevented. On the other hand, when the content of the volatile corrosion inhibitor 115 added to the package body 110 exceeds 5%, the reflectance of the package body 110 may be reduced and injection molding may be difficult.

In addition, for example, in order to prevent the discoloration of the first and second lead frames 122 and 124 and to increase the reflectance of the package body 110, the weight of the volatile corrosion inhibitor relative to the entire weight of the package body 110 may range from 0.5% to 3%.

In addition, for example, various conductive materials may be used as materials of the first and second lead frames 122 and 124. In order to ensure reliable prevention of discoloration and corrosion for these various conductive materials, the weight of the volatile corrosion inhibitor relative to the entire weight of the package body 110 may range from 1% to 2%.

The shape of the package body 110 viewed from the top side may be any one of various shapes such as, for example, a triangular, rectangular, polygonal, or circular shape according to the use purpose and design of the light-emitting device 130.

The package body 110 may have a cavity 105 that is defined by a bottom 101 and a lateral surface 102. The cavity 105 may be formed in the upper surface of the package body 110, and may be formed in, for example, a cup shape or a concave container shape. The lateral surface 102 of the cavity 105 may be inclined relative to the bottom 101 or the upper surfaces of the first and second lead frames 122 and 124. The inclination angle θ1 may be greater than 0 degrees and equal to or less than 90 degrees.

The cavity 105 illustrated in FIG. 1 may be realized in a polygonal (e.g. rectangular or octagonal), circular, or oval shape when viewed from the top side, without being limited thereto.

The first lead frame 122 and the second lead frame 124 are disposed on the package body 110 so as to be electrically separated from each other.

For example, the first lead frame 122 and the second lead frame 124 may be spaced apart from each other, and the bottom 101 of the cavity 105 may be located between the first lead frame 122 and the second lead frame 124.

A portion of the first lead frame 122 and a portion of the second lead frame 124 may be exposed by the cavity 105. For example, the upper surface of the first lead frame 122 and the upper surface of the second lead frame 124 may be exposed by the cavity 105.

In addition, each of the first lead frame 122 and the second lead frame 124 may penetrate the package body 110 so as to be exposed outward.

For example, one end 122a of the first lead frame 122 may be exposed outward from a first lateral surface of the package body 110, and one end 124a of the second lead frame 124 may be exposed outward from a second lateral surface of the package body 110. For example, the first lateral surface and the second lateral surface of the package body 110 may face each other, without being limited thereto.

The first lead frame 122 and the second lead frame 124 may be formed of a conductive material such as a metal, for example, titanium (Ti), copper (Cu), nickel (Ni), gold (Au), chrome (Cr), tantalum (Ta), platinum (Pt), tin (Sn), silver (Ag), and phosphorous (P), or an alloy thereof, and may be formed into a single layer or multiple layers.

The light-emitting device 130 is disposed in the cavity 105 of the package body 110.

The light-emitting device 130 may be electrically connected to the first lead frame 122 and the second lead frame 124. For example, the light-emitting device 130 may be disposed on the upper surface of the first lead frame 122, which is exposed by the cavity 105, and may be connected to the upper surface of the first lead frame 122 and the upper surface of the second lead frame 124 via the wires 152 and 154. For example, the light-emitting device 130 may be a chip-type light-emitting diode.

The adhesive member 135 is disposed between the light-emitting device 130 and the upper surface of the first lead frame 122, and attaches the light-emitting device 130 to the upper surface of the first lead frame 122. The adhesive member 135 may be non-conductive paste (e.g. silicone paste) or conductive paste (e.g. Ag paste).

For example, the adhesive member 135 may be formed of solder paste in which solder powder and flux are mixed with each other.

The light-emitting device 130 may be bonded to the upper surface of the first lead frame 122 via die bonding. The die bonding may include paste bonding by which a chip is attached to a substrate (or a lead frame) using non-conductive paste (e.g. silicone paste) or conductive paste (e.g. Ag paste), eutetic bonding by which a metal (e.g. Au/Sn) is formed on a chip pad and the metal (e.g. Au/Sn) is attached to a substrate at a high temperature, and flip chip bonding by which a chip pad and a substrate (or a lead frame) are directly connected to each other using a solder.

The first wire 152 may electrically interconnect the light-emitting device 130 and the upper surface of the first lead frame 122, and the second wire 154 may electrically interconnect the light-emitting device 130 and the upper surface of the second lead frame 124.

The resin layer 160 seals the light-emitting device 130 and the wires 152 and 154.

For example, the cavity 105 may be filled with the resin layer 160 so that the light-emitting device 130 and the wires 152 and 154 are surrounded by the resin layer 160. For example, the resin layer 160 may be a light-transmissive and insulative resin such as epoxy or silicon, and the cavity 105 may be filled with the resin layer 160 using, for example, dispensing.

The resin layer 160 may include a fluorescent substance that converts the wavelength of light emitted from the light-emitting device 130. In addition, the resin layer 160 may include a diffuser agent that diffuses light.

Although the resin layer 160 illustrated in FIG. 2 includes no volatile corrosion inhibitor, in order to reinforce the anti-corrosion of the first and second lead frames, in another embodiment, the resin layer 160 may include a volatile corrosion inhibitor. Alternatively, when the resin layer 160 includes the volatile corrosion inhibitor in another embodiment, no volatile corrosion inhibitor may be included in the package body.

Generally, since silicon used as a material of the resin layer of the light-emitting device package has a gas permeable property, the introduction of external gas may be completely prevented. Gas that has passed through the resin layer may cause corrosion and discoloration of the lead frame of the light-emitting device package, and the intensity of light of the light-emitting device package may be deteriorated due to the corrosion and discoloration of the lead frame.

In addition, solder flux may be used in the adhesive member 135 in order to attach the light-emitting device to the lead frame. The solder flux includes fatty acid that causes corrosion of the lead frame. For example, fatty acid including a —COOH group and the lead frame may undergo a chemical oxidation reaction, which may form an oxide layer on the surface of the lead frame and may cause discoloration of the lead frame.

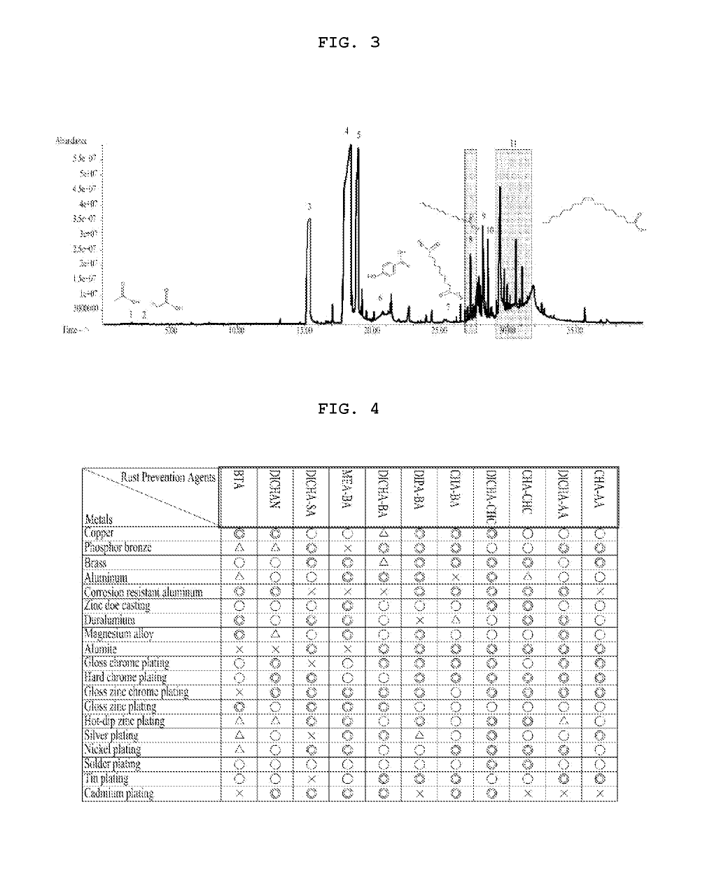

FIG. 3 is a view illustrating the result of analysis of gas volatized from solder flux.

Referring to FIG. 3, it can be found that various kinds of volatile gases are generated over time. No. 1 indicates acetic acid, No. 2 indicates acrylic acid, Nos. 3 and 4 indicate ethanol, No. 5 indicates butane, No. 6 indicates benzoic acid, No. 7 indicates decanedioic acid, No. 8 indicates hexadecanoic acid, No. 9 indicates 5-ethoxy-4-phenyl-2-isopropylpheno, No. 10 indicates 4b,8-Dimethyl-2-isopropylphenanthrene, and No. 11 indicates oleic acid.

It can be found that a large amount of oleic acid and hexadecanoic acid, which is one type of fatty acid, is detected in volatile gases.

In addition, water molecules, which have passed through the resin layer, or have been introduced through the interface between the package body and the resin layer, are dissociated into H+ and OH− ions under a highly humid environmental condition. The dissociated H+ and OH− ions may form a hydroxide and an activated Ag of the lead frame, which may cause discoloration of the lead frame.

FIG. 4 is a table illustrating the prevention of metal corrosion by the volatile corrosion inhibitor 115 included in the package body 110. The condition for metal corrosion may be a temperature of 50° C., a relative humidity of 90%, and a period of 70 days.

Referring to FIG. 4, ⊚ indicates that corrosion prevention is good, ◯ indicates that corrosion prevention is not good, Δ indicates the corrosion is not prevented, and x indicates that corrosion is not prevented or that corrosion is accelerated.

It can be found that the volatile corrosion inhibitor that has a good corrosion prevention function varies depending on the type of metal (e.g. copper or aluminum).

For example, BTA, DICHAN, DIPA•BA, CHA•BA, and DICHA•CHC may have a good corrosion prevention function for copper.

In addition, for example, MEA•BA, DICHA•BA, DIPA•BA, and DICHA•CHC may have a good corrosion prevention function for aluminum.

The package body 110 according to the embodiment may include a corrosion prevention volatile corrosion inhibitor that corresponds with the material of the first and second lead frames 122 and 124 based on the table illustrated in FIG. 4.

The volatile corrosion inhibitor 115 may be volatized at room temperature or during the driving of the light-emitting device 130. The volatile corrosion inhibitor 115 that has been volatized may undergo a chemical reaction with the first and second lead frames 122 and 124, and the first and second lead frames 122 and 124 that have undergone the chemical reaction with the volatized corrosion inhibitor 115 may not be corroded by fatty acid included in solder flux or moisture that has passed through the resin layer 160.

In addition, the volatile corrosion inhibitor 115 added to the package body 110 may directly react with fatty acid included in the adhesive member 135, thereby suppressing the activation of fatty acid. Thereby, the corrosion of the first and second frames 122 and 124 due to fatty acid may be suppressed.

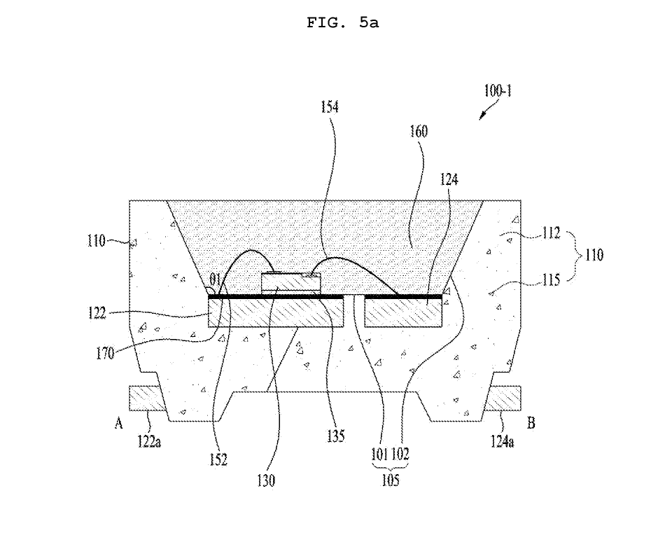

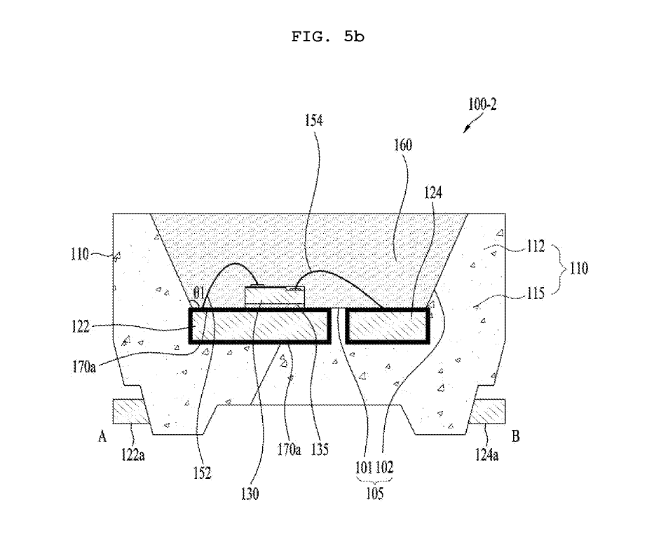

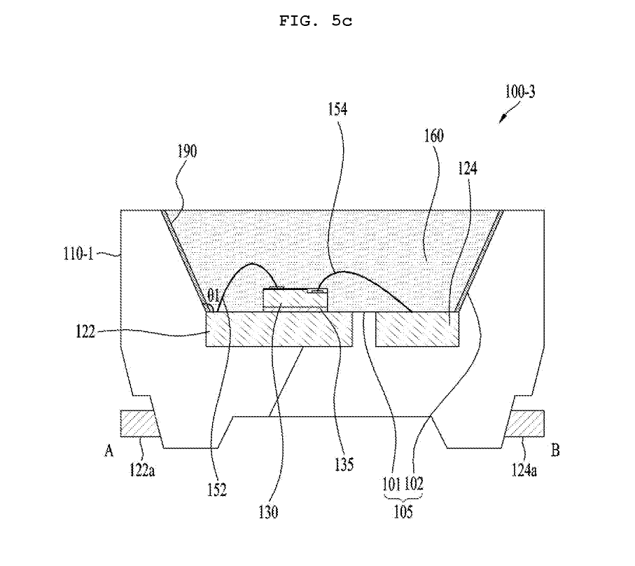

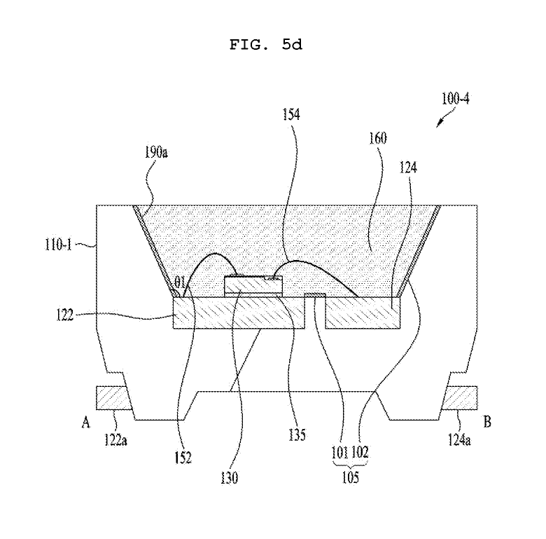

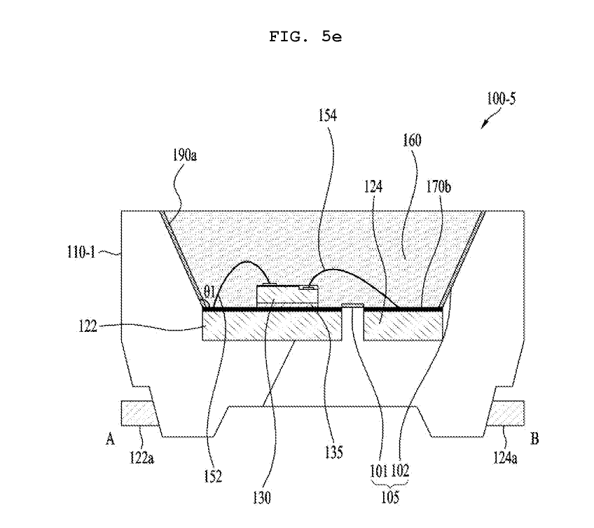

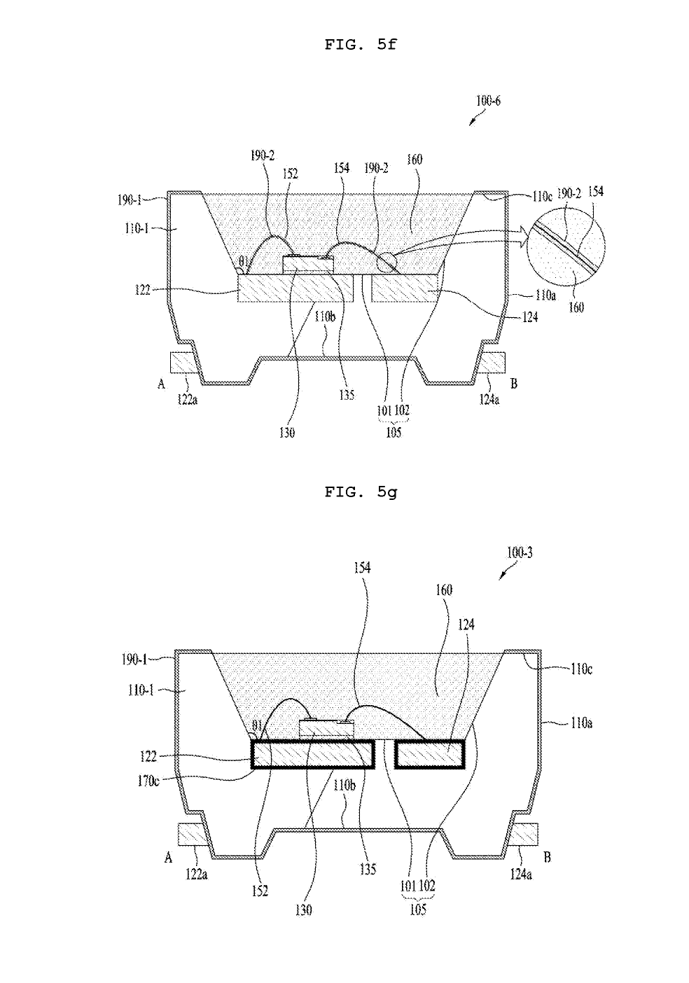

FIG. 5a is a cross-sectional view illustrating a light-emitting device package 100-1 according to another embodiment. The same reference numerals as those of FIG. 2 designate the same components, and a description related to the same components will be briefly provided or omitted.

Referring to FIG. 5a, the light-emitting device package 100-1 includes the package body 110, the first lead frame 122, the second lead frame 124, the light-emitting device 130, the adhesive member 135, the wires 152 and 154, the resin layer 160, and an anti-corrosion layer 170.

The light-emitting device package 100-1 illustrated in FIG. 5a may be configured such that the anti-corrosion layer 170 is added to the light-emitting device package 100 illustrated in FIGS. 1 and 2.

The anti-corrosion layer 170 may be formed on the upper surfaces of the first and second lead frames 122 and 124. The anti-corrosion layer 170 may be a protective layer that protects the first and second lead frames 122 and 124 from corrosion.

The package body 110 may include the volatile corrosion inhibitor 115. The volatile corrosion inhibitor 115 may be volatized at room temperature or during the driving of the light-emitting device 130. The upper surfaces of the first and second lead frames 122 and 124 may chemically react with the volatized corrosion inhibitor 115, and the anti-corrosion layer 170 may be formed on the upper surfaces of the first and second lead frames 122 and 124 via a chemical reaction.

The anti-corrosion layer 170 may be the product resulting from a chemical reaction between the volatile corrosion inhibitor 115, which is added to the package body 110, and the first and second lead frames 122 and 124. That is, the anti-corrosion layer 170 may be a compound that is produced by a chemical reaction between a metal that is a material of the first and second lead frames 122 and 124 and the volatile corrosion inhibitor 115.

Since the anti-corrosion layer 170 covers the upper surfaces of the first and second lead frames 122 and 124, the anti-corrosion layer 170 may prevent the surfaces of the first and second lead frames 122 and 124 from being corroded by moisture that has passed through the resin layer 160.

In addition, a portion of the anti-corrosion layer 170 may also be formed on the upper surface of the first lead frame 122 that is located below the adhesive member 135, and may prevent the first and second lead frames 122 and 124 from being corroded by fatty acid included in the adhesive member 135.

FIG. 5b is a cross-sectional view illustrating a light-emitting device package 100-2 according to another embodiment. The same reference numerals as those of FIG. 2 designate the same components, and a description related to the same components will be briefly provided or omitted.

Referring to FIG. 5b, the light-emitting device package 100-2 is an alternative embodiment of FIG. 5a, and an anti-corrosion layer 170a may be formed not only on the upper surfaces of the first and second lead frames 122 and 124, but also on the lateral surfaces and the lower surfaces of the first and second lead frames 122 and 124. The upper surfaces, lateral surfaces, and lower surfaces of the first and second lead frames 122 and 124 may undergo a chemical reaction with the volatized corrosion inhibitor 115, and with this chemical reaction, the anti-corrosion layer 170a may be formed on the upper surfaces, lateral surfaces, and lower surfaces of the first and second lead frames 122 and 124.

FIG. 5c is a cross-sectional view illustrating a light-emitting device package 100-3 according to another embodiment. The same reference numerals as those of FIGS. 2 and 5a designate the same components, and a description related to the same components will be briefly provided or omitted.

Referring to FIG. 5c, the light-emitting device package 100-3 includes a package body 110-1, the first lead frame 122, the second lead frame 124, the light-emitting device 130, the adhesive member 135, the wires 152 and 154, the resin layer 160, and an anti-corrosion member 190.

Unlike the embodiment illustrated in FIG. 5a, the package body 110-1 illustrated in FIG. 5c may be formed of a resin including no volatile corrosion inhibitor 115, and the anti-corrosion member 190 including a volatile corrosion inhibitor may be disposed on the surface of the package body 110-1.

The package body 110-1 may differ from the package body 110 only in terms of the constituent material thereof, but may have the same shape, without being limited thereto. For example, the package body 110-1 may have the cavity 105 that is defined by the bottom 101 and the lateral surface 102.

The anti-corrosion member 190 may be disposed on the lateral surface 102 of the cavity 105 of the package body 110-1. The anti-corrosion member 190 may be a mixture of a resin and a volatile corrosion inhibitor, and may be coated over the lateral surface 102 of the cavity 105 of the package body 110-1 or may be attached to the lateral surface 102 of the cavity 105 of the package body 110-1 via an adhesive.

The anti-corrosion member 190 may be a protective member that protects the first and second lead frames 122 and 124 from corrosion.

The volatile corrosion inhibitor included in the anti-corrosion member 190 volatized at room temperature or during the driving of the light-emitting device 130. The volatile corrosion inhibitor 115 that has been volatized may undergo a chemical reaction with the first and second lead frames 122 and 124, and an anti-corrosion layer may be formed on the surfaces of the first and second lead frames 122 and 124 via the chemical reaction.

In addition, the anti-corrosion member 190 may prevent the first and second lead frames 122 and 124 from being corroded by fatty acid included in solder flux or moisture that has passed through the resin layer 160. Thereby, the embodiment 100-3 may prevent deterioration in the intensity of light.

FIG. 5d is a cross-sectional view illustrating a light-emitting device package 100-4 according to another embodiment.

Compared with FIG. 5c, an anti-corrosion member 190a may be disposed not only on the lateral surface of the cavity 105 of the package body 110-1, but also on the bottom 101 of the cavity 105. The anti-corrosion member 190a may be a mixture of a resin and a volatile corrosion inhibitor, and may be coated over the lateral surface 102 and the bottom 101 of the cavity 105 of the package body 110-1 or may be attached to the lateral surface 102 and the bottom 101 of the cavity 105 of the package body 110-1 via an adhesive.

FIG. 5e is a cross-sectional view illustrating a light-emitting device package 100-5 according to another embodiment.

Referring to FIG. 5e, a volatile corrosion inhibitor included in the anti-corrosion member 190a of the light-emitting device package 100-4 of FIG. 5d may be volatized at room temperature or during the driving of the light-emitting device 130. The volatile corrosion inhibitor that has been volatized may undergo a chemical reaction with the first and second lead frames 122 and 124, and an anti-corrosion layer 170b may be formed on the surfaces of the first and second lead frames 122 and 124 via the chemical reaction. Although the anti-corrosion layer 170b is illustrated in FIG. 5e as being formed on the upper surfaces of the first and second lead frames 122 and 124, in another embodiment, the anti-corrosion layer 170b may be formed on at least one of the upper surfaces, lateral surfaces, and lower surfaces of the first and second lead frames 122 and 124.

The anti-corrosion layer 170b may be a compound that is produced via a chemical reaction between the volatile corrosion inhibitor included in the anti-corrosion member 190a and a metal that is a material of the first and second lead frames 122 and 124.

The anti-corrosion layer 170b may prevent the first and second lead frames 122 and 124 from being corroded by or fatty acid included in solder flux or moisture that has passed through the resin layer 160. Thereby, the embodiment 100-5 may prevent deterioration in the intensity of light.

FIG. 5f is a cross-sectional view illustrating a light-emitting device package 100-6 according to another embodiment. The same reference numerals as those of FIG. 5a designate the same components, and a description related to the same components will be briefly provided or omitted.

Referring to FIG. 5f, the light-emitting device package 100-6 includes the package body 110-1, the first lead frame 122, the second lead frame 124, the light-emitting device 130, the adhesive member 135, the wires 152 and 154, the resin layer 160, and a first anti-corrosion member 190-1.

The first anti-corrosion member 190-1 may be disposed on at least one of a lateral surface 110a, a lower surface 110b, and an upper surface 110c of the package body 110-1. The anti-corrosion member 190-1 may be a mixture of a resin and a volatile corrosion inhibitor, and may be coated over at least one of the lateral surface 110a, the lower surface 110b, and the upper surface 110c of the package body 110-1 or may be attached to at least one of the lateral surface 110a, the lower surface 110b, and the upper surface 110c of the package body 110-1 via an adhesive.

Since the first anti-corrosion member 190-1 is not disposed on the bottom 101 and the lateral surface 102 of the cavity 105 of the package body 110-1, but disposed on the lateral surface 110a, the lower surface 110b, or the upper surface 110c of the package body 110-1, deterioration in the reflectivity of the package body 110-1 may be prevented, which may increase luminous efficacy. This is because the first anti-corrosion member 190-1 may have lower reflectivity than the package body 110-1.

An anti-corrosion layer may be formed on the surfaces of the first and second lead frames 122 and 124 via a chemical reaction with a volatile corrosion inhibitor included in the first anti-corrosion member 190-1.

The light-emitting device package 100-6 may further include a second anti-corrosion member 190-2, which surrounds the wires 152 and 154 and includes a volatile corrosion inhibitor. The second anti-corrosion member 190-2 may have the same role as the first anti-corrosion member 190-1.

FIG. 5g is a cross-sectional view illustrating another embodiment 100-7 of the light-emitting device package illustrated in FIG. 5f.

Referring to FIG. 5g, a volatile corrosion inhibitor, which is included in the anti-corrosion member 190-1 of the light-emitting device package 100-6 illustrated in FIG. 5f, may be volatized at room temperature or during the driving of the light-emitting device 130. The volatile corrosion inhibitor that has been volatized may undergo a chemical reaction with the first and second lead frames 122 and 124, and with this chemical reaction, an anti-reflection layer 170c may be formed on the surfaces of the first and second lead frames 122 and 124, for example, at least one of the upper surfaces, lateral surfaces, or lower surfaces of the first and second lead frames 122 and 124. In addition, the anti-corrosion layer 170c may prevent the first and second frames 122 and 124 from being corroded by fatty acid included in solder flux or moisture that has passed through the resin layer 160, and thus the embodiment 100-7 may prevent deterioration in luminous flux.

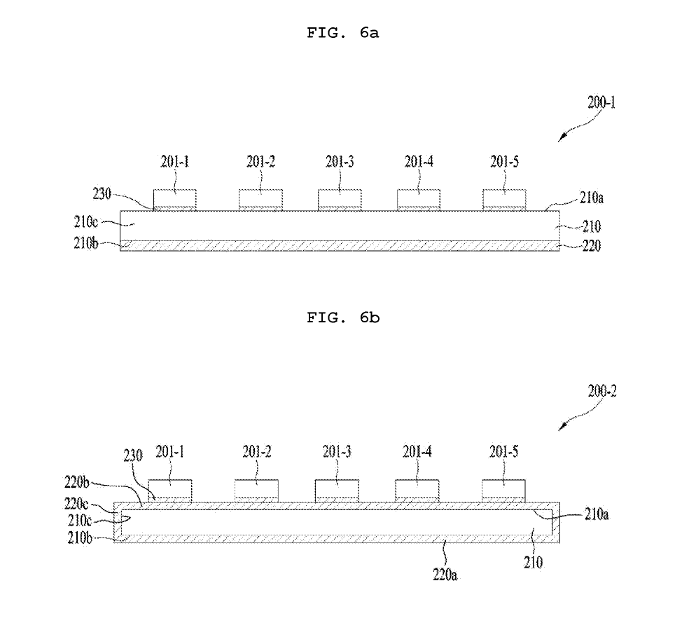

FIG. 6a illustrates a light-emitting module 200-1 according to an embodiment.

Referring to FIG. 6a, the light-emitting module 200-1 may include a board 210, an anti-corrosion member 220, a plurality of light-emitting device packages 201-1 to 201-5, and an adhesive member 230.

The board 210 may be a printed circuit board. The board 210 may have a bar shape, for example, a rectangular shape, without being limited thereto. The board 210 may be a flexible circuit board.

The board 210 may be formed into a single-layered board or a multi-layered board. In the case of a multi-layered board, it may be a copper clad laminate that is coated with copper multiple times. The base material of the board 210 may be a resin such as, for example, epoxy, phenol, polyimide, flame retardant 4 (FR-4) or composite epoxy material grade 3 (CEM-3), and a reinforcement material such as, for example, glass fiber or paper may be added in order to increase the strength of the board 210.

The light-emitting device packages 201-1 to 201-5 are spaced apart from each other on the board 210. For example, the light-emitting device packages 201-1 to 201-5 may be disposed in a line or in a matrix form on the upper surface 210a of the board 210.

Each of the light-emitting device packages 201-1 to 201-5 may be a light-emitting device package according to the embodiment of FIG. 2 in which the volatile corrosion inhibitor 115 is removed from the package body 110.

Alternatively, each of the light-emitting device packages 201-1 to 201-5 may be the embodiment 100 described in FIGS. 1 and 2, or any one of the embodiments 100-1 to 100-7 described in FIGS. 5a to 5g.

The adhesive member 230 may be disposed between the light-emitting device packages 201-1 to 201-5 and the board 210. The adhesive member 230 may be disposed between the light-emitting device packages 201-1 to 201-5 and the upper surface 210a of the board 210, and may attach the light-emitting device packages 201-1 to 201-5 to the upper surface 210a of the board 210.

The adhesive member 230 may be non-conductive paste (e.g. silicone paste) or conductive paste (e.g. Ag paste). For example, the adhesive member 230 may be a solder or solder paste. The adhesive member 230 may be the same material as the adhesive member 135 described in FIGS. 1 and 2, without being limited thereto.

The anti-corrosion member 220 may be disposed on at least one of the upper surface, the lower surface, or the lateral surface of the board 210.

The anti-corrosion member 220 may include a resin and a volatile corrosion inhibitor. For example, the anti-corrosion member 220 may be formed by adding or mixing a resin to or with a volatile corrosion inhibitor. The volatile corrosion inhibitor included in the anti-corrosion member 220 may be the same as the volatile corrosion inhibitor 115 described in FIGS. 1 and 2. The anti-corrosion member 220 may be attached to the lower surface 210b of the board 210 via an adhesive tape.

The volatile corrosion inhibitor included in the anti-corrosion member 220 may be volatized at room temperature or during the driving of the light-emitting device packages 201-1 to 201-5. The volatile corrosion inhibitor that has been volatized may penetrate the resin layer 160 of the light-emitting device packages 201-1 to 201-5 or may be introduced into the interface between the package body 110 and the resin layer 160, thereby undergoing a chemical reaction with the first and second lead frames 122 and 124. The first and second lead frames 122 and 124, which has undergone the chemical reaction with the volatized corrosion inhibitor, may not be corroded by fatty acid included in solder flux or moisture that has passed through the resin layer 160.

In addition, the volatile corrosion inhibitor, volatized from the anti-corrosion member 220, may directly react with fatty acid included in the adhesive member 230, thereby preventing the activation of fatty acid, which may prevent the first and second lead frames 122 and 124 from being corroded by fatty acid.

FIG. 6b illustrates a light-emitting module 200-2 according to another embodiment.

Referring to FIG. 6b, the anti-corrosion member 220 may include a first prevention member 220a disposed on the lower surface 210b of the board 210, a second prevention member 220b disposed on the upper surface 210a of the board 210, and a third prevention member 220c disposed on the lateral surface 210c of the board 210. The description related to the anti-corrosion member 200 of FIG. 6A may be applied to the first to third prevention members.

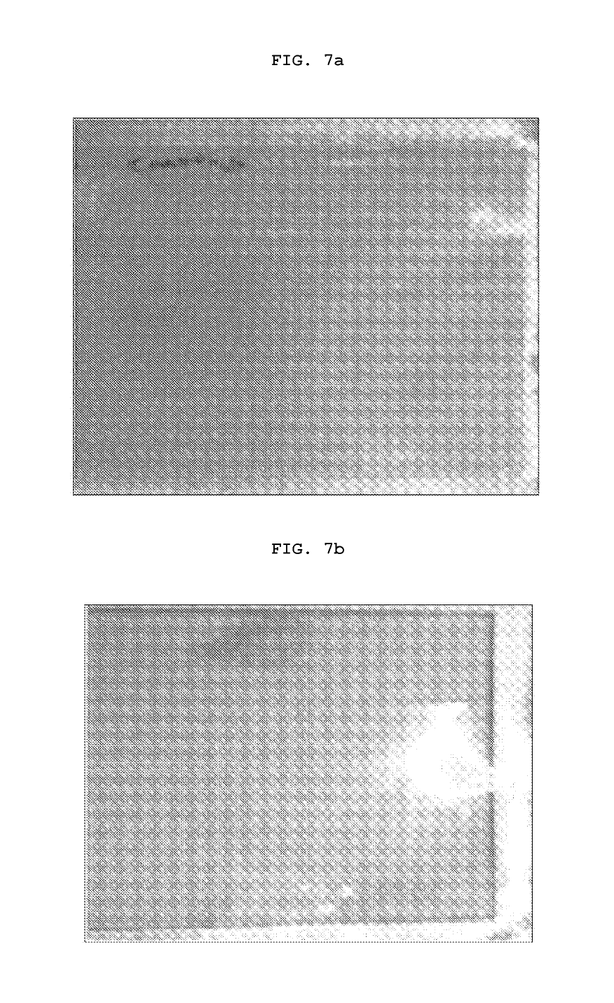

FIG. 7a is a view illustrating a result of discoloration experimentation on an adhesive member of a light-emitting module that does not include the anti-corrosion member 220 illustrated in FIG. 6a, and FIG. 7b is a view illustrating a result of discoloration experimentation on the adhesive member 230 of the light-emitting module 200 illustrated in FIG. 6a. The experimentation condition is the temperature of 60° C., the humidity of 90%, and the period of 4 days, and the adhesive member is Ag paste.

In FIG. 7a, Ag paste may be discolored via a reaction between activated Ag and fatty acid included in the adhesive member. On the other hand, in FIG. 7b, the volatile corrosion inhibitor, volatized from the anti-corrosion member 220, bonds with the fatty acid included in the adhesive member 230, which may suppress the reaction of fatty acid and Ag paste, and thus may prevent the discoloration of Ag paste. That is, the embodiment may prevent the discoloration of the adhesive member 230, for example, Ag paste, by the anti-corrosion member 230, thereby preventing deterioration in the luminous efficacy of the light-emitting module.

In addition, the volatile corrosion inhibitor, volatized from the anti-corrosion member 220, may undergo a chemical reaction with the surfaces, for example, the upper surfaces of the first and second lead frames 122 and 124, and with this chemical reaction, the anti-corrosion layer 170 may be formed on the surfaces of the first and second lead frames 122 and 124 as described above in FIG. 5. The anti-corrosion layer 170 may prevent the first and second lead frames 122 and 124 from being corroded by moisture.

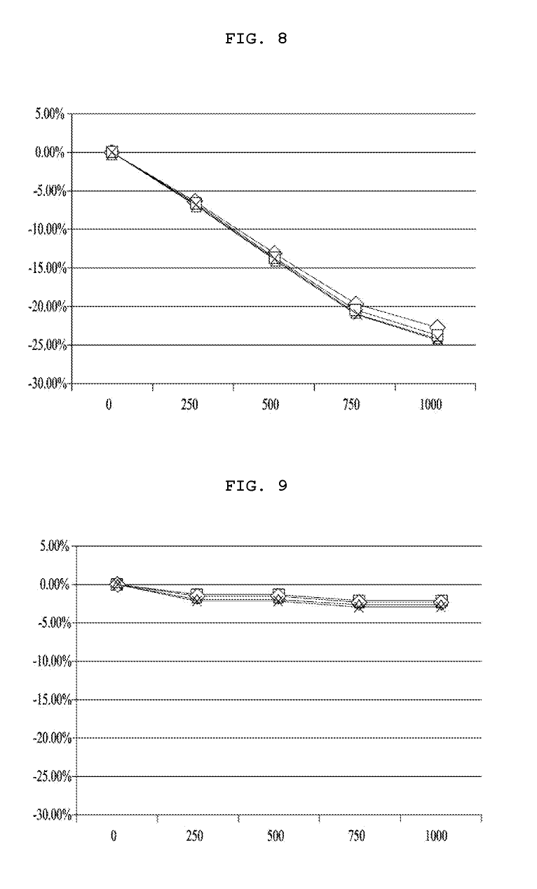

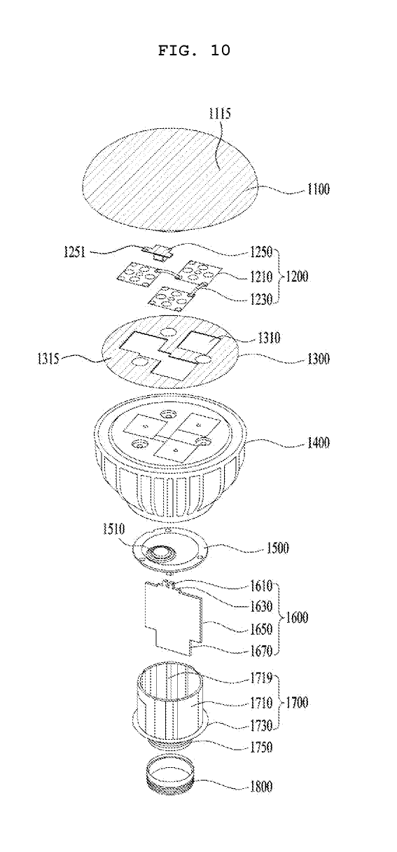

FIG. 8 is a view illustrating a result of experimentation showing variation in luminous flux over time in the light-emitting module that does not include the anti-corrosion member 220 illustrated in FIG. 6a, and FIG. 9 is a view illustrating a result of experimentation showing variation in luminous flux over time in the light-emitting module 200 illustrated in FIG. 6a. The x-axis represents lapsed time (hour), and the y-axis represents the luminous flux reduction rate.

Referring to FIG. 8, it can be found that the luminous flux of the light-emitting module is gradually reduced since the lead frames of the light-emitting device packages are discolored as time passes. It can be found that the luminous flux of the light-emitting module is reduced by 20% or more after 1000 hour have passed.

Referring to FIG. 9, it can be found that the luminous flux reduction rate of the light-emitting module is below 5% even if the time has passed. The volatile corrosion inhibitor included in the anti-corrosion member 220 may prevent the discoloration of the lead frames 122 and 124 of the light-emitting device packages 201-1 to 201-5, which may prevent deterioration in the luminous flux of the light-emitting module 200.

FIG. 10 is a view illustrating a lighting apparatus including a light-emitting device package according to an embodiment.

Referring to FIG. 10, the lighting apparatus may include a cover 1100, an anti-corrosion member 1115, a light source module 1200, a radiator 1400, a power supply unit 1600, an inner case 1700, and a socket 1800. In addition, the lighting apparatus according to the embodiment may further include any one of a member 1300 and a holder 1500.

The cover 1100 may have a bulb shape or a semispherical shape, and may be empty, and a portion of the cover 1100 may be opened. The cover 1100 may be optically coupled to the light source module 1200. For example, the cover 1100 may diffuse, scatter, or excite light provided from the light source module 1200. The cover 1100 may be one kind of an optical member.

The cover 1100 may be coupled to the radiator 1400. The cover 1100 may have a coupling portion to be coupled to the radiator 1400.

The inner surface of the cover 1100 may be coated with an ivory white paint. The ivory white paint may include a diffuser that diffuses light. The surface roughness of the inner surface of the cover 1100 may be greater than the surface roughness of the outer surface of the cover 1100. This serves to sufficiently scatter and diffuse light from the light source module 1200 so as to emit the light outward.

The cover 1100 may be formed of glass, plastic, polypropylene PP, polyethylene PE, or polycarbonate PC. Here, polycarbonate has excellent light-resistance, heat-resistance, and strength. The cover 1100 may be transparent so as to allow the light source module 1200 to be visible from the outside, without being limited thereto, and may be opaque. The cover 1100 may be formed via blow molding.

The anti-corrosion member 1115 is disposed on the surface of the cover 1110. For example, the anti-corrosion member 1115 may be coated over the surface of the cover 1110. The anti-corrosion member 1115 may be acquired by adding a volatile corrosion inhibitor to a resin, or by mixing the volatile corrosion inhibitor and the resin with each other. The above description related to the anti-corrosion members 190 and 220 may be equally applied to the anti-corrosion member 1115.

The light source module 1200 may be disposed on one surface of the radiator 1400, and heat generated from the light source module 1200 may be transferred to the radiator 1400. The light source module 1200 may include a light source unit 1210, a connection plate 1230, and a connector 1250. The light source unit 1210 may include the light-emitting device packages 100, 100-1 to 100-7 according to the embodiments, or the light-emitting module 200.

The member 1300 may be disposed on the upper surface of the radiator 1400, and may have a guide recess 1310 into which multiple light source units 1210 and the connector 1250 are inserted. The guide recess 1310 may correspond to or may be aligned with substrates of the light source units 1210 and the connector 1250. In order to prevent the corrosion of the lead frames of the light-emitting device package, the surface of the connector 1250 may be coated with an anti-corrosion member 1251.

A light reflective material may be applied to or coated over the surface of the member 1300.

For example, an ivory white paint may be applied to or coated over the surface of the member 1300. The member 1300 may reflect light, which has been reflected by the inner surface of the cover 1100 and returned to the light source module 1200, toward the cover 1100. Thus, the luminous efficacy of the lighting apparatus according to the embodiment may be increased.

The member 1300 may be formed of, for example, an insulating material. In addition, in order to prevent the corrosion of the lead frames of the light-emitting device package, an anti-corrosion member 1315 may be coated over the surface of the member 1300. Alternatively, in another embodiment, a volatile corrosion inhibitor may be added to or mixed in the member 1300.

The connection plate 1230 of the light source module 1200 may include an electrically conductive material. Thus, the electrical contact between the radiator 1400 and the connection plate 1230 may be achieved. The member 1300 may be formed of an insulating material so as to prevent electrical short-circuit between the connection plate 1230 and the radiator 1400. The radiator 1400 may radiate heat transferred from the light source module 1200 and heat transferred from the power supply unit 1600.

The holder 1500 closes an accommodating recess 1719 in an insulating portion 1710 of the inner case 1700. Thus, the power supply unit 1600, which is accommodated in the insulating portion 1710 of the inner case 1700, may be sealed. The holder 1500 may have a guide protrusion 1510, and the guide protrusion 1510 may have a hole, through which a protruding portion 1610 of the power supply unit 1600 passes.

The power supply unit 1600 processes and converts an electrical signal received from the outside and provides the same to the light source module 1200. The power supply unit 1600 may be accommodated in the accommodating recess 1719 in the inner case 1700 and may be sealed inside the inner case 1700 by the holder 1500. The power supply unit 1600 may include the protruding portion 1610, a guide portion 1630, a base 1650, and an extension 1670.

The guide portion 1630 may protrude outward from one side of the base 1650. The guide portion 1630 may be inserted into the holder 1500. Multiple elements may be disposed on one surface of the base 1650. The multiple elements may include, for example, a DC converter that converts AC power, supplied from an external power source, into DC power, a drive chip that controls the driving of the light source module 1200, and an electrostatic discharge (ESD) protective element that protects the light source module 1200, without being limited thereto.

The extension 1670 may protrude outward from the other side of the base 1650. The extension 1670 may be inserted into a connecting portion 1750 of the inner case 1700, and may receive an external electrical signal. For example, the extension 1670 may have a width that is equal to or less than the width of the connecting portion 1750 of the inner case 1700. One end of each of a “positive electric wire” and a “negative electric wire” may be electrically connected to the extension 1670, and the other end of each of the “positive electric wire” and the “negative electric wire” may be electrically connected to the socket 1800.

The inner case 1700 may include a molding portion, in addition to the power supply unit 1600, therein. The molding portion is a solidified portion of molding liquid. The power supply unit 1600 may be fixed inside the inner case 1700.

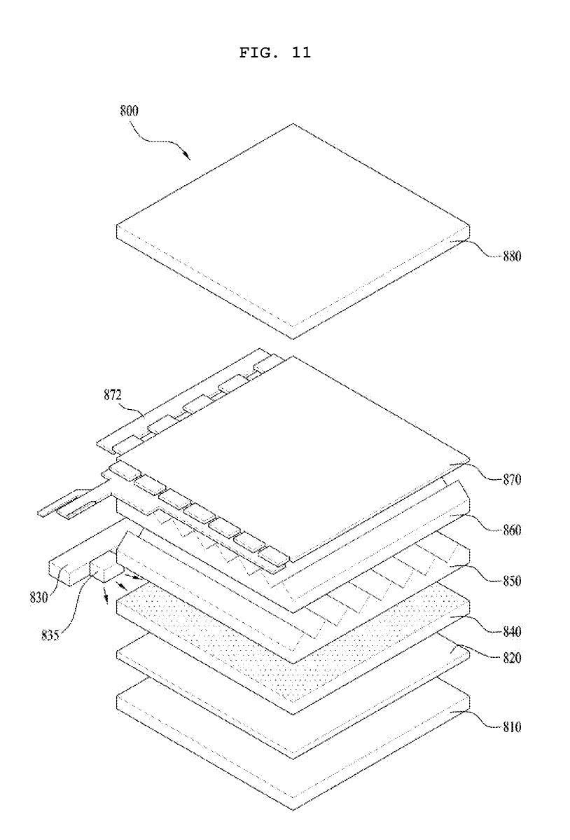

FIG. 11 is a view illustrating a display apparatus including a light-emitting device package according to an embodiment.

Referring to FIG. 11, the display apparatus 800 may include a bottom cover 810, a reflector 820 that is disposed on the bottom cover 810, light-emitting modules 830 and 835 that emit light, a light guide plate 840 that is disposed in front of the reflector 820 and guides the light emitted from the light-emitting modules 830 and 835 to the front side of the display apparatus, an optical sheet that includes prism sheets 850 and 860 disposed in front of the light guide plate 840, a display panel 870 disposed in front of the optical sheet, an image signal output circuit 872 that is connected to the display panel 870 and supplies an image signal to the display panel 870, and a color filter 880 that is disposed in front of the display panel 870. Here, the bottom cover 810, the reflector 820, the light-emitting modules 830 and 835, the light guide plate 840, and the optical sheet may constitute a backlight unit.

The light-emitting module may include light-emitting device packages 835 mounted on a board 830. Here, the board 830 may be, for example, a PCB. The light-emitting device package 835 may be any one of the above-described embodiments 100 and 100-1. Alternatively, the light-emitting module may be any one of the embodiments 200-1 and 200-2 illustrated in FIGS. 6a and 6b.

The bottom cover 810 may accommodate constituent elements in the display apparatus 800. In addition, the reflector 820 may be configured as a separate element as illustrated in FIG. 11, or may be formed by coating the back surface of the light guide plate 840 or the front surface of the bottom cover 810 with a highly reflective material.

Here, the reflector 820 may be formed of a material that has high reflectance and may be used in an ultra thin form. The reflector 820 may be formed of polyethylene terephthalate (PET).

In addition, the light guide plate 840 may be formed of, for example, a polymethylmethacrylate (PMMA), polycarbonate (PC), or polyethylene (PE).

In addition, the first prism sheet 850 may be formed on one surface of a support film using an elastic polymer material having light transmittance. The polymer material may include a prism layer in which multiple stereoscopic structures is repeatedly formed. Here, the multiple patterns, as illustrated, may be arranged in stripes in which valleys and ridges are repeated.

In addition, in the second prism sheet 860, the direction in which ridges and valleys are formed on one surface of a support film may be perpendicular to the direction in which the ridges and valleys are formed on one surface of the support film in the first prism sheet 850. This serves to uniformly distribute the light transmitted from the light-emitting module and the reflector to the display panel 870 in all directions.

In addition, although not illustrated, a diffuser sheet may be disposed between the light guide plate 840 and the first prism sheet 850. The diffuser sheet may be formed of polyester and polycarbonate based materials, and may increase the light emission angle of light introduced from the backlight unit to the maximum extent via refraction and scattering. In addition, the diffuser sheet may include a support layer that includes a light diffuser, and a first layer and a second layer that are formed on a light-emitting surface (facing the first prism sheet) and a light-receiving surface (facing the reflector) and does not include the light diffuser.

In the embodiment, the diffuser sheet, the first prism sheet 850, and the second prism sheet 860 constitute the optical sheet. The optical sheet may be formed in another combination, for example, a micro-lens array, a combination of a diffuser sheet and a micro-lens array, or a combination of a prism sheet and a micro-lens array.

The display panel 870 may be a liquid crystal display panel, or may be another type of display apparatus that requires a light source excluding the liquid crystal display panel 860.

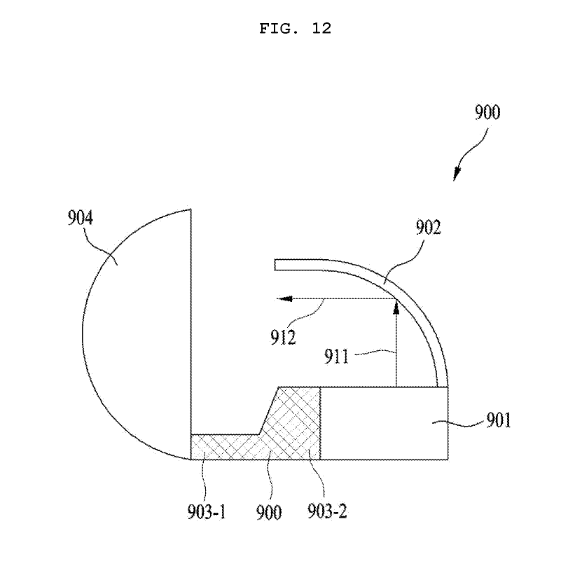

FIG. 12 is a view illustrating a headlamp 900 including a light-emitting device package according to the embodiment. Referring to FIG. 12, the headlamp 900 includes a light-emitting module 901, a reflector 902, a shade 903, and a lens 904.

The light-emitting module 901 may include multiple light-emitting device packages (not illustrated) disposed on a board (not illustrated). At this time, the light-emitting device package 835 may be any one of the above-described embodiments 100 and 100-1. Alternatively, the light-emitting module 901 may be any one of the embodiments 200-1 and 200-2 illustrated in FIG. 6a or 6b.

The reflector 902 reflects light 911 emitted from the light-emitting module 901 in a given direction, for example, in a front direction 912.

The shade 903 is a member that is disposed between the reflector 902 and the lens 904, and blocks or reflects part of the light that is reflected by the reflector 902 and directed toward the lens 904, so as to achieve a light distribution pattern intended by the designer. One side portion 903-1 and the other side portion 903-2 of the shade 903 may have different heights.

Light emitted from the light-emitting module 901 may be reflected by the reflector 902 and the shade 903, and thereafter may be directed forward by passing through the lens 904.

Although the exemplary embodiments have been illustrated and described as above, it will of course be apparent to those skilled in the art that the embodiments are provided to assist understanding and the embodiments are not limited to the above description, and various modifications and variations can be made in the embodiments without departing from the spirit or scope of the disclosure, and the modifications and variations should not be understood individually from the viewpoint or scope of the disclosure so long as they include the constituent elements set forth in the claims.

### INDUSTRIAL APPLICABILITY

The present invention may be used in a lighting apparatus, a display apparatus, and a headlamp that includes a light-emitting device package.

1. A light-emitting device package comprising:
a package body;
a lead frame disposed on the package body;
a light-emitting device disposed on the lead frame;
an adhesive member disposed between the light-emitting device and the lead frame; and
a resin layer surrounding the light-emitting device,
wherein the package body includes a resin and a volatile corrosion inhibitor, and the volatile corrosion inhibitor is mixed with the resin.

2. The package according to claim 1, wherein the volatile corrosion inhibitor includes at least one selected from among Benzo triazole (BTA), Tolyltriazole (TTA), Dicyclohexyl ammonium nitrite (DICHAN), Dicyclohexyl ammonium salicylate (DICHA-SA), Monoethanolamine benzoate (MEA-BA), Dicyclohexyl ammonium benzoate (DICHA-BA), Diisopropyl ammonium benzoate (DIPA-BA), Diisopropyl ammonium nitrite (DIPAN), Cyclohexylamine carbonate (CHC), Nitro naphthalene ammonium nitrite (NITAN), Cyclohexylamine benzoate (CHA-BA), Dicyclohexyl ammonium cyclohexylamine carboxylate (DICHA-CHC), Cyclohexylamine cyclohexane carboxylate (CHA-CHC), Dicyclohexyl ammonium acrylate (DICHA-AA), and Cyclohexylamine acrylate (CHA-AA).

3. The package according to claim 1, wherein the volatile corrosion inhibitor has a weight within a range from 0.01% to 5% relative to an entire weight of the package body.

4. The package according to claim 1, wherein the volatile corrosion inhibitor has a weight within a range from 0.5% to 3% relative to an entire weight of the package body.

5. The package according to claim 1, wherein the volatile corrosion inhibitor has a weight within a range from 1% to 2% relative to an entire weight of the package body.

6. The package according to claim 1, further comprising a protective layer formed on a surface of the lead frame,
wherein the protective layer is a compound resulting from a chemical reaction between the lead frame and the volatile corrosion inhibitor.

7. The package according to claim 6, wherein the protective layer is formed on at least one of an upper surface, a lateral surface, and a lower surface of the lead frame.

8. The package according to claim 1, wherein the resin layer includes a volatile corrosion inhibitor.

9. A light-emitting device package comprising:
a package body having a cavity including a lateral surface and a bottom;
a lead frame disposed on the package body;
a light-emitting device disposed on the lead frame inside the cavity;
an adhesive member disposed between the light-emitting device and the lead frame;
a first protective member disposed on a surface of the package body;
a protective layer formed on at least one of an upper surface, a lateral surface, and a lower surface of the lead frame; and
a resin layer that is filled in the cavity so as to surround the light-emitting device,
wherein the first protective member is disposed on at least one of the lateral surface of the cavity, the bottom of the cavity, a lateral surface of the package body, a lower surface of the package body, and an upper surface of the package body,
wherein the first protective member includes a volatile corrosion inhibitor
wherein the protective layer is a compound resulting from a chemical reaction between the lead frame and the volatile corrosion inhibitor included in the first protective member.

10.-13. (canceled)

14. The package according to claim 9, wherein the volatile corrosion inhibitor includes at least one selected from among Benzo triazole (BTA), Tolyltriazole (TTA), Dicyclohexyl ammonium nitrite (DICHAN), Dicyclohexyl ammonium salicylate (DICHA-SA), Monoethanolamine benzoate (MEA-BA), Dicyclohexyl ammonium benzoate (DICHA-BA), Diisopropyl ammonium benzoate (DIPA-BA), Diisopropyl ammonium nitrite (DIPAN), Cyclohexylamine carbonate (CHC), Nitro naphthalene ammonium nitrite (NITAN), Cyclohexylamine benzoate (CHA-BA), Dicyclohexyl ammonium cyclohexylamine carboxylate (DICHA-CHC), Cyclohexylamine cyclohexane carboxylate (CHA-CHC), Dicyclohexyl ammonium acrylate (DICHA-AA), and Cyclohexylamine acrylate (CHA-AA).

15. The package according to claim 9, wherein the lead frame is formed of at least one selected from among titanium (Ti), copper (Cu), nickel (Ni), gold (Au), chrome (Cr), tantalum (Ta), platinum (Pt), tin (Sn), silver (Ag), and phosphorous (P), or an alloy thereof.

16. The package according to claim 9, further comprising:
a wire configured to electrically interconnect the light-emitting device and the lead frame; and
a second protective member configured to surround the wire, the second protective member including a volatile corrosion inhibitor.

17. The package according to claim 9, wherein the adhesive member is a solder or solder paste.

18. A light-emitting module comprising:
a board;
a plurality of light-emitting device packages disposed on an upper surface of the board;
a first adhesive member disposed between the light-emitting device packages and the board; and
a protective member disposed on at least one of an upper surface, a lateral surface, and a lower surface of the board, the protective member including a volatile corrosion inhibitor,
wherein each of the light-emitting device packages includes:
a package body;
a lead frame disposed on the package body;
a light-emitting device disposed on the lead frame;
a second adhesive member disposed between the light-emitting device and the lead frame; and
a resin layer surrounding the light-emitting device,
wherein each of the light-emitting device packages further includes a protective layer formed on at least one of an upper surface, a lateral surface, and a lower surface of the lead frame, and
wherein the protective layer is a compound resulting from a chemical reaction between the lead frame and the volatile corrosion inhibitor included in the protective member.

19. (canceled)

20. (canceled)

21. The package according to claim 9, wherein the protective member further includes a resin mixed with the volatile corrosion inhibitor.

22. The package according to claim 18, wherein the protective member further includes a resin mixed with the volatile corrosion inhibitor.

23. The package according to claim 18, wherein the lead frame is formed of at least one selected from among titanium (Ti), copper (Cu), nickel (Ni), gold (Au), chrome (Cr), tantalum (Ta), platinum (Pt), tin (Sn), silver (Ag), and phosphorous (P), or an alloy thereof.

24. The package according to claim 18, wherein each of the first adhesive member and the second adhesive member is a solder or solder paste.

25. The package according to claim 18, wherein the volatile corrosion inhibitor includes at least one selected from among Benzo triazole (BTA), Tolyltriazole (TTA), Dicyclohexyl ammonium nitrite (DICHAN), Dicyclohexyl ammonium salicylate (DICHA-SA), Monoethanolamine benzoate (MEA-BA), Dicyclohexyl ammonium benzoate (DICHA-BA), Diisopropyl ammonium benzoate (DIPA-BA), Diisopropyl ammonium nitrite (DIPAN), Cyclohexylamine carbonate (CHC), Nitro naphthalene ammonium nitrite (NITAN), Cyclohexylamine benzoate (CHA-BA), Dicyclohexyl ammonium cyclohexylamine carboxylate (DICHA-CHC), Cyclohexylamine cyclohexane carboxylate (CHA-CHC), Dicyclohexyl ammonium acrylate (DICHA-AA), and Cyclohexylamine acrylate (CHA-AA).

26. The package according to claim 18, wherein the lead frame is formed of at least one selected from among titanium (Ti), copper (Cu), nickel (Ni), gold (Au), chrome (Cr), tantalum (Ta), platinum (Pt), tin (Sn), silver (Ag), and phosphorous (P), or an alloy thereof.
